(19) United States
(12) Patent Application Publication
(10) Pub. No.: US 2003/0123238 A1
(43) Pub. Date: Jul. 3, 2003

(54) Enhanced PCB and stacked substrate structure

(76) Inventors: Chia-Hsing Yu, Sanchung City (TW); Ching-Fu Chuang, Taipei (TW)

Correspondence Address: RABIN & CHAMPAGNE, PC, 1101 14TH STREET, NW, SUITE 500, WASHINGTON, DC, 20005, US

(21) Appl. No.: 10/300,736

(22) Filed: Nov. 21, 2002

(30) Foreign Application Priority Data
Dec. 27, 2001 (TW) 90132614

(51) Int. Cl. H05K 7/02; H05K 7/06; H05K 7/08; H05K 7/10

(52) U.S. Cl. 361/780

(57) ABSTRACT

An enhanced Printed Circuit Board (PCB) and stacked substrate structure. In one embodiment, each middle layer is coupled between two ground layers except for the top signal layer and the bottom solder layer. In another embodiment, the top signal layer and the bottom solder layer are respectively coupled between two ground layers, so all signal layers are implemented in the stacked substrate structure and any internal signal layer is coupled between two ground layers. Thus, all signals can refer to adjacent ground layers and achieve better signal quality. Also, each capacitance structure formed by a signal layer and a ground layer increases the operating speed of the entire circuit.

### BACKGROUND OF THE INVENTION

1. Field of the Invention

The present invention relates to an enhanced Printed Circuit Board (PCB) and stacked substrate structure, especially to a Stacked substrate PCB structure to provide a signal layer adjacent to one or more ground layers such that all signals (trace routes) refer to the ground layer(s) and thus achieve preferred high frequency signal quality.

2. Description of Related Art

Conventionally, PCBs for predetermined operations and stacked substrate structures are essentially four or six layers, respectively shown in FIGS. 1 and 2. FIG. 1 is a cross-section of a conventional four-layer structure. In FIG. 1, the four-layer structure shows a component layer 11 with electronic components at the top for circuit operation, a power layer 12 below the component layer 11 for operating power supply, a ground layer 13 below the power layer 12 for ground potential supply as a reference, and a solder layer 14 at the bottom for solder. FIG. 2 is a cross-section of a conventional six-layer structure. In FIG. 2, the six-layer structure shows a component layer 21 with electronic components at the top for circuit operation, a power layer 22 below the component layer 21 for operating power supply, adjacent internal signal layers 23 and 24 below the power layer 22 for internal signal tracks, a ground layer 25 below the internal signal layer 24 for ground potential supply as a reference, and a solder layer 26 at the bottom for solder. As shown in FIGS. 1 and 2, the cited layers have alternating insulation layers 100 for electrical signal isolation. The component layers 11 and 21 include various electronic components mounted thereon. The power layers 12 and 22 comprise power lines to supply power to the respective structure. The ground layers 13 and 25 include ground lines to reduce impedance of the structure. The solder layers 14 and 26 are connected to other circuits for electrical communication. The internal signal layers 23 and 24 are signal-enhanced layers. However, the cited four- or six-structure has only a ground layer. As such, when signals are running on the wiring of the structure, the structure cannot completely avoid errors from noise, especially during high frequency signal transmission.

Accordingly, another six-structure in U.S. Pat. No. 5,719,750 is shown in FIG. 3. The six-layer structure includes the following layers from top to bottom: component 31-power 32-ground 33-internal signal 34-ground 35-component 36. The cited layers also have alternating insulation layers 100 for electrical signal isolation. This structure can eliminate cited errors from noise except for signals between the component layer 31 and the power layer 32 where no ground layer exists. This may further incur EMI from internal or external interference through the component layer, damaging the structure.

### SUMMARY OF THE INVENTION

Accordingly, an object of the invention is to provide an enhanced Printed Circuit Board (PCB) and stacked substrate structure, which provides at least one ground layer adjacent to a signal layer such that all signals completely refer to the at least one ground layer and have better quality for high frequency signals.

In a first embodiment of the invention, except where the top signal layer and the bottom solder layer are connected to a ground layer, any middle signal layer or power layer is layered between two ground layers. For example, a five-layer structure in this embodiment is signal (component)-ground-power-ground-solder. As such, all signals refer to the adjacent ground layer.

In a second embodiment of the invention, two ground layers are added on the top and the bottom of a stacked structure and all signal layers and power layers are implemented in the middle of the structure, thereby layering any internal signal layer or power layer between two ground layers. For example, a five-layer structure in this embodiment is ground-component-ground-power-ground. As such, all signals can also refer to adjacent ground layer.

As cited, when the structure of the invention applies to Central Processing Unit (CPU) substrates, PCBs, and chipsets, it has an optimizing return path and better signal integrity. Additionally, due to the capacitance structure formed between signal layer and ground layer, it further increases the operating speed of the entire circuit.

### BRIEF DESCRIPTION OF THE DRAWINGS

The invention will become apparent by referring to the following detailed description of a preferred embodiment with reference to the accompanying drawings, wherein:

FIG. 1 is a cross-section of a conventional four-layer structure;

FIG. 2 is a cross-section of a conventional six-layer structure;

FIG. 3 is a cross-section of another conventional six-layer structure;

FIG. 4 is a cross-section of a first five-layer PCB and stacked substrate structure implementation according to the invention; and

FIG. 5 is a cross-section of a second five-layer PCB and stacked substrate structure implementation according to the invention.

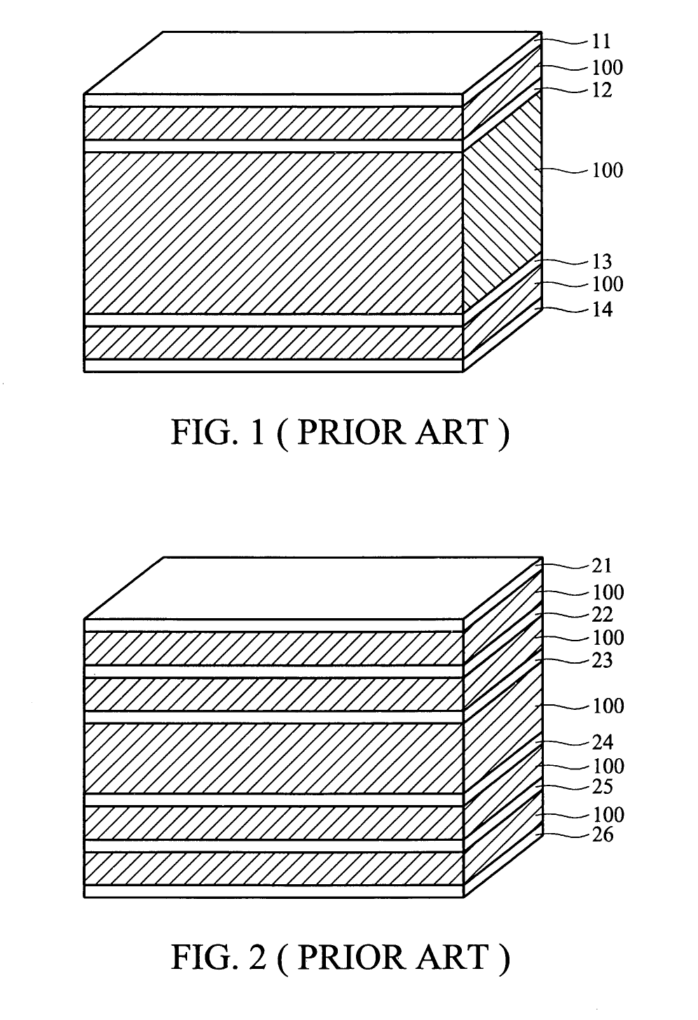

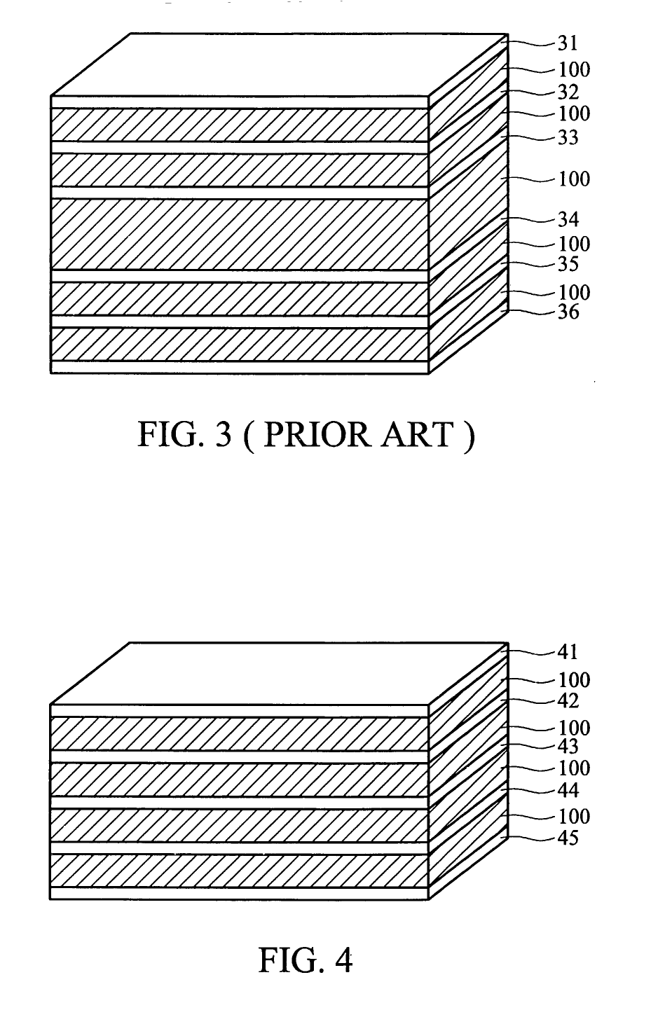

### DETAILED DESCRIPTION OF THE INVENTION

FIG. 4 is a cross-section of a first five-layer PCB and stacked substrate structure implementation according to the invention. In FIG. 4, the five-layer structure from top to bottom shows a component layer 41, a ground layer 42, a power layer 43, a ground layer 44 and a solder layer 45. As shown in FIG. 4, the bottom solder layer 45 is used to solder and wire to other circuits for signal communication. For example, a chipset can connect to other circuits, such as a host board or a modem board, through the solder layer 45. The solder layer 45 is a conductive material, for example, gold, Sn, or others. The ground layer 44 over the solder layer 45 connects to an external grounding line (not shown) to provide a required reference to internal operating signals by keeping the ground potential. The power layer 43 over the ground layer 44 connects to an external power supply (not shown) to provide the structure's power and a source of electrical signal. The ground layer 42 over the power layer 43 connects to the external grounding line (not shown), the same as the ground layer 44, to provide a required reference to internal operating signals by keeping the ground potential. The component layer 41 over the ground layer 42 can be mounted on various components to receive or transmit signal for corresponding functionality. All cited layers have alternating insulation layers 100 for electrical signal isolation between layers and to keep the entire operation normal. The insulation layer 100 can be, for example, ceramic. As such, the invention is characterized by a ground layer immediately adjacent to each signal layer. For example, a component layer 41 refers to the ground layer 42 while a power layer 43 can refer to the ground layer 42 or 44. All signals are delivered accurately because of the immediately adjacent ground layer. Additionally, the solder layer 45, formed of conductive materials such as Sn and gold, may cause errors in signal delivery. Accordingly, the inventive layer implementation arranges the solder layer 45 referring to the ground layer 44 for further assuring operating signals are accurately delivered to avoid noise interference.

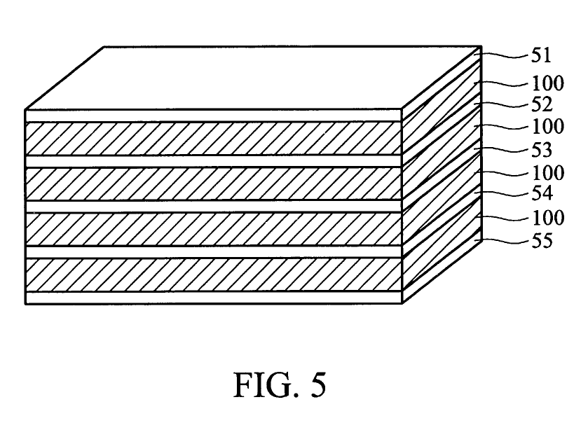

FIG. 5 is a cross-section of a second five-layer PCB and stacked substrate structure implementation according to the invention. In FIG. 5, this structure is basically interlaced between a signal layer and a ground layer. Compared to the implementation of FIG. 4, this structure lacks a solder layer, which does not affect the entire operation. As shown in FIG. 5, two ground layers 51, 55 are added on the top and the bottom and other signal and power layers 52, 54 in the middle are layered with a ground layer 53 to avoid, for example typical noise interference produced by signal delivery between the component layer 52 and the power layer 54. Still, all cited layers have alternating insulation layers 100 for electrical signal isolation between layers. Also, this structure has an additional advantage of preventing EMI.

Substantially, the embodiments can be applied to any odd-layer structure (for example five-layer, seven-layer and so on) as any signal layer including power layer, solder layer, internal signal layer and the like is immediately adjacent to at least one ground layer to provide grounding potential as a reference. Therefore, when a signal layer at the top and a solder layer at the bottom are implemented in a stacked substrate structure, such a structure includes a total number of ground layers one less than the signal layers. As shown in an example in FIG. 4, the total number of the signal layers including the solder layer is 3, and the total number of ground layers is 2. Alternately, when a ground layer is implemented respectively at the top and the bottom of the structure, such a structure includes a total number of ground layers that is one more than the signal layers. As shown in an example in FIG. 5, the total number of the signal layers is 2 and the total number of the ground layers is 3. In practice, the number of layers of a stacked substrate structure and its implementation varies with required applications. Additionally, the operating speed of the entire circuit is increased because a capacitance structure is formed between a signal layer and a ground layer, for example, between the ground layer 42 and the power layer 43 as well as the power layer 43 and the ground layer 44.

Although the present invention has been described in its preferred embodiments, it is not intended to limit the invention to the precise embodiments disclosed herein. Those who are skilled in this technology can still make various alterations and modifications without departing from the scope and spirit of this invention. Therefore, the scope of the present invention shall be defined and protected by the following claims and their equivalents.

What is claimed is:

1. An enhanced Printed Circuit Board (PCB) and stacked substrate structure, comprising:
at least one signal layer, to provide an operating signal for the structure; and
a plurality of ground layers, at least one of which is connected adjacent to the at least one signal layer through an insulation layer, to provide the operating signal with a gounding reference potential and thus avoid signal error caused by noise interference.

2. The structure of claim 1, wherein the at least one signal layer is a component layer having electronics to produce required functions for the structure or a power layer externally connected to a power supply for powering the structure.

3. The structure of claim 1, wherein the at least one signal layer is a solder layer connected to an external circuit through a conductive material.

4. The structure of claim 3, wherein the conductive material is tin (Sn) or gold.

5. The structure of claim 1, wherein the insulation layer is ceramic.

6. The structure of claim 1, wherein the stacked substrate structure has a top signal layer adjacent to one of the ground layers, a bottom solder layer adjacent to the other ground layer and at least one internal signal layer layered between one and the other ground layers.

7. The structure of claim 6, wherein in the stacked substrate structure, the total number of signal layers is one more than the ground layers.

8. The structure of claim 1, wherein the stacked substrate structure has a top ground layer, a bottom ground layer, and a plurality of internal signal layers, wherein either the top or bottom ground layer is adjacent to one of the internal signal layers, and each of the internal signal layers is layered between two of the ground layers.

9. The structure of claim 8, wherein in the stacked substrate structure, the total number of signal layers is one less than the ground layers.

10. The structure of claim 1, wherein the stacked substrate structure is in a Central Processing Unit (CPU) substrate, a Printed Circuit Board (PCB) or a chipset.

11. An enhanced Printed Circuit Board (PCB) and stacked substrate structure, characterized in that a bottom solder layer communicates with external circuits by a bottom solder layer connected to external circuits using a conductive material; a first ground layer over the bottom solder layer provides the bottom solder layer with a constant grounding potential reference by connecting the first ground layer to an external grounding line; a power layer over the first ground layer provides the structure with a source of power and electrical signal; a second ground layer over the power layer provides the power layer with constant grounding potential reference by connecting the second ground layer to the external grounding line; and a component layer over the second ground layer is mounted with electronics to receive and transmit signals for performing electronics functions under the constant grounding potential reference provided by the second ground layer; wherein an insulation layer is layered between two of the solder layer, first ground layer, power layer, second ground layer, and the component layer.

12. The structure of claim 11, wherein the conductive material is tin (Sn) or gold, and the insulation layer is ceramic.

13. The structure of claim 11, wherein the stacked substrate structure is in a Central Processing Unit (CPU) substrate, a Printed Circuit Board (PCB), or a chipset.

14. An enhanced Printed Circuit Board (PCB) and stacked substrate structure, comprising:
a plurality of signal layers, at least one of which provides an operating signal for the structure; and
a plurality of ground layers, each connected adjacent to one of the signal layers through an insulation layer that is ceramic, wherein at least one of the ground layers is connected adjacent to the at least one signal layers to provide the operating signal with grounding reference potential to avoid signal error caused by noise interference;
wherein the total number of the signal layers and the ground layers is an odd number.

15. The structure of claim 14, wherein the stacked substrate structure has a top signal layer adjacent to one of the ground layers, a bottom solder layer adjacent to the other ground layer and at least one internal signal layer layered between the ground layers.

16. The structure of claim 15, wherein in the stacked substrate structure, the total number of the signal layers is one more than the ground layers.

17. The structure of claim 14, wherein the stacked substrate structure has a top ground layer, a bottom ground layer, and a plurality of internal signal layers, wherein either the top ground layer or the bottom ground layer is adjacent to one of the internal signal layers, and each of the internal signal layers is layered between two of the ground layers.

18. The structure of claim 17, wherein in the stacked substrate structure, the total number of the signal layers is one less than the ground layers.

19. The structure of claim 14, wherein the signal layers comprise a solder layer for connection to an external circuit using a tin (Sn) or gold conductive material.

20. The structure of claim 14, wherein the stacked substrate structure is in a Central Processing Unit (CPU) substrate, a Printed Circuit Board (PCB) or a chipset.
